(19) United States
(12) Patent Application Publication
(10) Pub. No.: US 2025/0023537 A1
(43) Pub. Date: Jan. 16, 2025

(54) BULK ACOUSTIC WAVE RESONATOR, MANUFACTURING METHOD THEREOF AND ELECTRONIC DEVICE

(71) Applicants: Beijing BOE Technology Development Co., Ltd., Beijing (CN); BOE TECHNOLOGY GROUP CO., LTD., Beijing (CN)

(72) Inventor: Xiyuan WANG, Beijing (CN)

(21) Appl. No.: 18/279,530

(22) PCT Filed: Jul. 26, 2022
(86) PCT No.: PCT/CN2022/107818

§ 371 Date: Aug. 30, 2023

(51) Int. Cl. H03H 9/02; H03H 3/02; H03H 9/17

(52) U.S. Cl. CPC H03H 9/02031; H03H 3/02; H03H 9/173; H03H 9/174; H03H 9/175; H03H 9/176; H03H 2003/021; H03H 2003/023; H03H 2003/025

(57) ABSTRACT

The present disclosure provides a bulk acoustic wave resonator, a method for manufacturing a bulk acoustic wave resonator and an electronic device, and belongs to the field of communication technology. The bulk acoustic wave resonator of the present disclosure includes: a first base substrate, a first electrode, a piezoelectric layer, and a second electrode; the first electrode is on the first base substrate, the second electrode is on a side of the first electrode away from the first base substrate, the piezoelectric layer is between the first electrode and the second electrode; and orthographic projections of any two of the first electrode, the piezoelectric layer and the second electrode on the first base substrate at least partially overlap with each other; wherein an acoustic velocity of a material of the piezoelectric layer is no less than 18000 m/s.

### TECHNICAL FIELD

The present disclosure relates to the field of communication technology, and in particular to a bulk acoustic wave resonator, a method for manufacturing a bulk acoustic wave resonator and an electronic device.

### BACKGROUND

In the field of mobile communications, the allocated total available frequency is in a narrow range, and there are many frequency bands used for the mobile communication, so that a spacing between adjacent frequency bands is narrow (about several MHz (megahertz) to tens of MHz), and a single frequency band has a narrow bandwidth (tens of MHz). Thus, a filter used in a mobile phone is required to have performance characteristics of a small in-band ripple, a large out-of-band rejection, and a good rectangularity. A conventional micro-strip filter has a large volume, an insufficient out-of-band rejection and a poor rectangularity and cannot meet the above requirement: a cavity filter has a large volume and cannot meet the above requirement: a dielectric filter has a large in-band insertion loss and a poor rectangularity and cannot meet the above requirement: an IPD (Integrated Passive Device) filter has a large in-band ripple and a poor rectangularity and cannot meet the above requirement.

A bulk acoustic wave resonator serves as an elementary unit of a structure of a bulk acoustic wave filter. The existing bulk acoustic wave resonator adopts a silicon wafer as a material of a substrate with a sandwich structure, including a first electrode, a piezoelectric material and a second electrode from bottom to top. An operating principle thereof is: a radio frequency signal enters into the resonator from an electrode at one end of the resonator, then is converted into an acoustic wave signal of mechanical vibration at an interface of the piezoelectric material and the metal electrode through an inverse piezoelectric effect: the acoustic wave signal is formed as a resonant standing wave with a certain frequency in the sandwich structure including the first electrode, the piezoelectric material and the second electrode: a frequency of the radio frequency signal is the same as a resonant frequency of the resonator: the acoustic wave signal is transmitted to the electrode at the other end of the resonator, and is converted into the radio frequency signal at the interface of the metal electrode and the piezoelectric material through a piezoelectric effect. The resonator has a fixed resonant frequency. When the frequency of the radio frequency signal is the same as the resonant frequency of the resonator, the conversion from the radio frequency signal to the acoustic wave signal to the radio frequency signal is high-efficiency: when the frequency of the radio frequency signal is not the same as the resonant frequency of the resonator, the conversion from the radio frequency signal to the acoustic wave signal to the radio frequency signal is low-efficiency, and most of the radio frequency signals cannot be transmitted through the resonator. That is, the resonator functions as a filter, which filters the radio frequency signals.

### SUMMARY

The present disclosure aims to solve at least one technical problem in the prior art, and provides a bulk acoustic wave resonator, a method for manufacturing a bulk acoustic wave resonator and an electronic device.

An embodiment of the present disclosure provides a bulk acoustic wave resonator, including: a first base substrate, a first electrode, a piezoelectric layer, and a second electrode: wherein the first electrode is on the first base substrate, the second electrode is on a side of the first electrode away from the first base substrate, the piezoelectric layer is between the first electrode and the second electrode; and orthographic projections of any two of the first electrode, the piezoelectric layer and the second electrode on the first base substrate at least partially overlap with each other: wherein an acoustic velocity of a material of the piezoelectric layer is not less than 18000 m/s.

In the embodiment of the present disclosure, the material of the piezoelectric layer includes any one of hBN, cBN, wBN.

In the embodiment of the present disclosure, the bulk acoustic wave resonator further includes an inducing layer between the first electrode and the piezoelectric layer, wherein an orthographic projection of the inducing layer on the first base substrate covers an orthographic projection of the piezoelectric layer on the first base substrate.

In the embodiment of the present disclosure, a material of the inducing layer includes graphene.

In the embodiment of the present disclosure, the bulk acoustic wave resonator further includes a first connecting electrode in a same layer as the second electrode, wherein the first connecting electrode is electrically connected to the first electrode through a first connecting via penetrating through the piezoelectric layer.

In the embodiment of the present disclosure, a material of the first electrode includes any one or more of Cu, Al, Mo, Co, Ag, Ti, Pt, Ru, W, Au.

In the embodiment of the present disclosure, the first base substrate includes a first cavity penetrating through the first base substrate in a thickness direction of the first base substrate: the first base substrate includes a first surface and a second surface opposite to each other in the thickness direction of the first base substrate: the first cavity includes a first opening and a second opening opposite to each other; and the first opening is in the first surface, and the second opening is in the second surface; and the first electrode covers the first opening.

In the embodiment of the present disclosure, the first base substrate includes a first groove: the first base substrate includes a first surface and a second surface opposite to each other in a thickness direction of the first base substrate: the first groove includes a third opening; and the third opening is in the first surface, the first electrode is on the first surface; and an orthographic projection of the first electrode on a plane of the second surface covers an orthographic projection of the third opening on the plane of the second surface.

In the embodiment of the present disclosure, the bulk acoustic wave resonator further includes an isolation layer between the first surface of the first base substrate and the first electrode.

In the embodiment of the present disclosure, the bulk acoustic wave resonator further includes at least one first through hole penetrating through the first electrode and the isolation layer, wherein the first via is connected to the first groove.

In the embodiment of the present disclosure, the bulk acoustic wave resonator further includes at least one mirror structure between the first electrode and the first base substrate: wherein each mirror structure includes a first sub-structure layer and a second sub-structure layer sequentially arranged in a direction away from the first base substrate, and an acoustic impedance of a material of the first sub-structure layer is greater than that of a material of the second sub-structure layer.

In the embodiment of the present disclosure, the bulk acoustic wave resonator further includes an encapsulation layer on a side of the second electrode away from the first base substrate, wherein the encapsulation layer covers the first electrode, the piezoelectric layer and the second electrode.

An embodiment of the present disclosure provides a method for manufacturing a bulk acoustic wave resonator, including: sequentially forming a first electrode, a piezoelectric layer and a second electrode on a first base substrate, wherein orthographic projections of any two of the first electrode, the piezoelectric layer and the second electrode on the first base substrate at least partially overlap with each other: wherein an acoustic velocity of a material of the piezoelectric layer is not less than 18000 m/s.

In the embodiment of the present disclosure, the material of the piezoelectric layer includes any one of hBN, cBN, wBN.

In the embodiment of the present disclosure, the forming the piezoelectric layer includes: forming the piezoelectric layer by a radio frequency magnetron sputtering.

In the embodiment of the present disclosure, the method for manufacturing a bulk acoustic wave resonator, before forming the first electrode and the piezoelectric layer, further includes: forming an inducing layer.

In the embodiment of the present disclosure, a first connecting electrode is formed at the same time as the second electrode: the method further includes: forming a first connecting via penetrating through the piezoelectric layer in a thickness direction of the piezoelectric layer, and the first connecting electrode is connected to the first electrode through the first connecting via.

In the embodiment of the present disclosure, the method for manufacturing a bulk acoustic wave resonator further includes: forming a first cavity penetrating through the first base substrate in a thickness direction of the first base substrate by processing the first base substrate: wherein the first base substrate includes a first surface and a second surface opposite to each other in the thickness direction of the first base substrate: the first cavity includes a first opening and a second opening opposite to each other; and the first opening is in the first surface, and the second opening is in the second surface; and the first electrode covers the first opening.

In the embodiment of the present disclosure, the method for manufacturing a bulk acoustic wave resonator further includes: forming a first groove by processing the first base substrate: wherein the first base substrate includes a first surface and a second surface opposite to each other in a thickness direction of the first base substrate: the first groove includes a third opening; and the third opening is in the first surface, the first electrode is on the first surface; and an orthographic projection of the first electrode on a plane of the second surface covers an orthographic projection of the third opening on the plane of the second surface.

In the embodiment of the present disclosure, the method for manufacturing a bulk acoustic wave resonator further includes: forming a filling structure in the first groove: forming an isolation layer on a side of the first groove away from the first base substrate: wherein the first electrode is formed on a side of the isolation layer away from the first base substrate; and forming a first through hole penetrating through the first electrode and the isolation layer, and removing the filling structure.

In the embodiment of the present disclosure, the method for manufacturing a bulk acoustic wave resonator, before forming the first electrode, further includes: forming at least one mirror structure on the first base substrate: wherein forming each mirror structure includes sequentially forming a first sub-structure layer and a second sub-structure layer in a direction away from the first base substrate, and an acoustic impedance of a material of the first sub-structure layer is greater than that of a material of the second sub-structure layer.

In the embodiment of the present disclosure, the method for manufacturing a bulk acoustic wave resonator further includes: forming an encapsulation layer on a side of the second electrode away from the first base substrate: wherein the encapsulation layer covers the first electrode, the piezoelectric layer, and the second electrode.

An embodiment of the present disclosure provides an electronic device, which includes the bulk acoustic wave resonator in any one of the above embodiments.

### BRIEF DESCRIPTION OF DRAWINGS

FIG. 1 is a schematic diagram of a back-etched bulk acoustic wave resonator.

FIG. 2 is a schematic diagram of a film bulk acoustic wave resonator.

FIG. 3 is a schematic diagram of a solid mounted bulk acoustic wave resonator.

FIG. 4 is a schematic diagram of a bulk acoustic wave resonator of a first example of an embodiment of the present disclosure.

FIG. 5 is a flow chart illustrating how to manufacture a bulk acoustic wave resonator shown in FIG. 4.

FIG. 6 is a schematic diagram of a bulk acoustic wave resonator of a second example of an embodiment of the present disclosure.

FIG. 7 is a flow chart illustrating how to manufacture a bulk acoustic wave resonator shown in FIG. 6.

FIG. 8 is a schematic diagram of a bulk acoustic wave resonator of a third example of an embodiment of the present disclosure.

FIG. 9 is a flow chart illustrating how to manufacture a bulk acoustic wave resonator shown in FIG. 8.

FIG. 10 is a schematic diagram of a bulk acoustic wave resonator of a fourth example of an embodiment of the present disclosure.

FIG. 11 is a flow chart illustrating how to manufacture a bulk acoustic wave resonator shown in FIG. 10.

FIG. 12 is a schematic diagram of a bulk acoustic wave resonator of a fifth example of an embodiment of the present disclosure.

FIG. 13 is a flow chart illustrating how to manufacture a bulk acoustic wave resonator shown in FIG. 12.

FIG. 14 is a schematic diagram of a bulk acoustic wave resonator of a sixth example of an embodiment of the present disclosure.

FIG. 15 is a flow chart illustrating how to manufacture a bulk acoustic wave resonator shown in FIG. 14.

### DETAIL DESCRIPTION OF EMBODIMENTS

In order to enable one of ordinary skill in the art to better understand the technical solutions of the present disclosure, the present disclosure will be described in further detail with reference to the accompanying drawings and the detailed description.

Unless defined otherwise, technical or scientific terms used herein shall have the ordinary meaning as understood by one of ordinary skill in the art to which the present disclosure belongs. The terms “first”, “second”, and the like used in the present disclosure are not intended to indicate any order, quantity, or importance, but rather are used for distinguishing one element from another. Further, the term “a”, “an”, “the”, or the like used herein does not denote a limitation of quantity, but rather denotes the presence of at least one element. The term “comprising”, “including”, or the like, means that the element or item preceding the term contains the element or item listed after the term and its equivalent, but does not exclude other elements or items. The term “connected”, “coupled”, or the like is not limited to a physical or mechanical connection, but may include an electrical connection, whether a direct or indirect connection. The terms “upper”, “lower”, “left”, “right”, and the like are used only for indicating relative positional relationships, and when the absolute position of an object being described is changed, the relative positional relationships may also be changed accordingly.

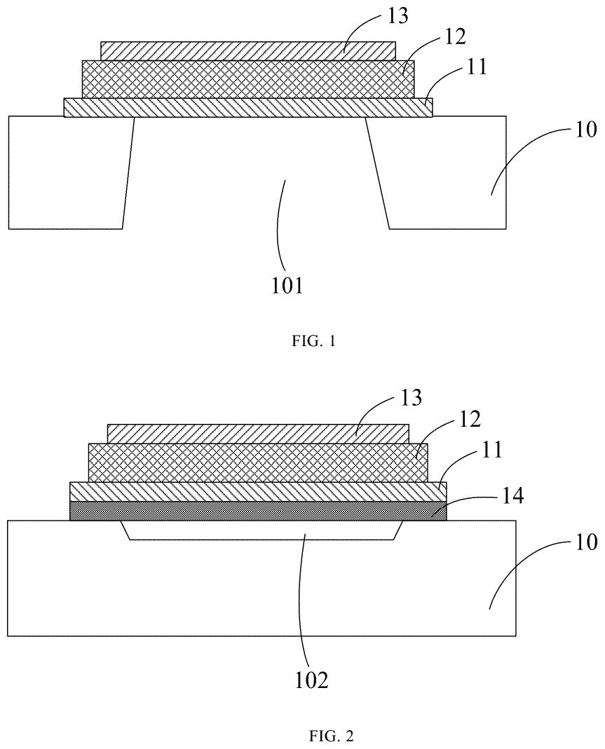

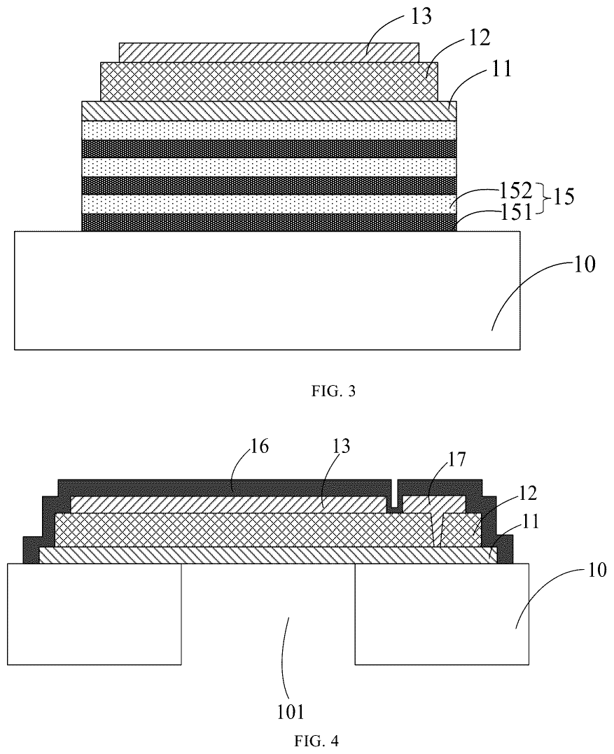

As shown in FIGS. 1 to 3, in order to reduce an insertion loss of a bulk acoustic wave resonator in a filtering process, it is necessary to limit an acoustic wave signal in a piezoelectric layer 12 between a first electrode 11 and a second electrode 13 as much as possible, to prevent the acoustic wave signal from diffusing out, so that acoustic wave reflectors are usually provided on upper and lower surfaces of the resonator. A reflector is generally provided on the upper surface and is made of an air medium with a low acoustic impedance. Depending on the acoustic wave reflectors provided on the lower surface, the bulk acoustic wave resonators are divided into three major classes, that is, a back-etched bulk acoustic wave resonator as shown in FIG. 1; a film bulk acoustic wave resonator (abbreviated as FBAR) as shown in FIG. 2; and a solid mounted resonator (abbreviated as SMR) as shown in FIG. 3. In the FBAR, a first groove 102 formed by etching under the first electrode on the first base substrate 10 as an air gap. In the SMR, high acoustic impedance layers 151 and low acoustic impedance layers 152 are alternately and repeatedly stacked under the first electrode 11 as an acoustic mirror 15. In the back-etched bulk acoustic wave resonator, a first cavity 101 is formed under the first electrode 11 in the first base substrate 10 as an air layer by forming a cavity by deep etching back on the back of a silicon substrate.

The existing bulk acoustic wave resonator may only be applied in a frequency range of 1 GHz to 6 GHZ and cannot be applied in a frequency band of larger than 6 GHZ. To address this issue, in the embodiments of the present disclosure, an acoustic velocity of a material of the piezoelectric layer in the bulk acoustic wave resonator is not less than 18000 m/s. For example: the piezoelectric layer is made of boron nitride, specifically hexagonal phase boron nitride, and the material not only has piezoelectric property, but also has an acoustic velocity as high as 18600 m/s, which is 64% higher than that of the conventional piezoelectric layer, so that the bulk acoustic wave resonator in the embodiment of the present disclosure may be applied in a higher frequency range. The bulk acoustic wave resonator made of the hexagonal phase boron nitride material has the advantages of low cost, high resonant frequency, small volume, low insertion loss, small in-band ripple, large out-of-band rejection and good rectangularity, and thus, is widely applied in various frequency bands larger than 1 GHZ, particularly frequency bands in a range of 6 GHz to 30 GHz in the field of mobile communication, and can effectively filter low-frequency interference signals and higher harmonics thereof in the ground environment. Thus, the signal quality of the mobile communication is improved.

The bulk acoustic wave resonator and a method for manufacturing a bulk acoustic wave resonator according to the embodiment of the present disclosure are described below with reference to specific examples.

In a first example is: FIG. 4 is a schematic diagram of a bulk acoustic wave resonator of the first example of an embodiment of the present disclosure. As shown in FIG. 4, the bulk acoustic wave resonator includes a first base substrate 10, and a first electrode 11, a piezoelectric layer 12, and a second electrode 13 sequentially disposed on the first base substrate 10, and orthographic projections of any two of the first electrode 11, the piezoelectric layer 12, and the second electrode 13 on the first base substrate 10 at least partially overlap with each other. An encapsulation layer 16 may also be provided on a side of the second electrode 13 away from the first base substrate 10. The first base substrate 10 is provided with a first cavity 101 penetrating through the first base substrate 10 in a thickness direction of the first base substrate 10. The first base substrate 10 includes a first surface (upper surface) and a second surface (lower surface) which are oppositely disposed in a thickness direction of the first base substrate 10, and the first cavity 101 includes a first opening formed in the first surface and a second opening formed in the second surface. The first electrode 11 is disposed on the first surface, and an orthographic projection of the first electrode 11 on a plane of the second surface covers an orthographic projection of the first opening on the plane of the second surface.

Further, in addition to the above structure, the bulk acoustic wave resonator further includes a first connecting electrode 17 disposed in the same layer as the second electrode 13, and connected to the first electrode 11 through a via penetrating through the piezoelectric layer 12. In this case, a radio frequency signal enters into the resonator from an upper left corner of FIG. 4, then is converted into an acoustic wave signal through an inverse piezoelectric effect at an interface between the second electrode 13 and the piezoelectric layer 12, and the acoustic wave signal is longitudinally transmitted in the piezoelectric layer 12, and is converted into a radio frequency signal through the piezoelectric effect at an interface between the first electrode 11 and the piezoelectric layer 12, and is transmitted upward through a conductive through hole at the lower right corner of the first electrode 11, and finally is transmitted outward at the upper right corner of the second electrode 13. The first cavity 101 below the resonator and the air layer above the resonator together act as an acoustic reflector, and are configured to confine the acoustic signal within the resonator structure rather than dissipating the acoustic signal out, thereby reducing the losses of the resonator.

In this example, a material of the piezoelectric layer 12 is preferably hBN, and may alternatively be cBN, wBN. Alternatively, the material of the piezoelectric layer 12 may be selected from AlN, ZnO, PZT, GaN, InN, CdS, CdSe, ZnS, CdTe, ZnTe, GaAs, GaSb, InAs, InSb, GaSe, GaP, AlP, quartz crystal, LiTaO3, LiNbO3, La3Ga5SiO14, BaTiO3, PbNb2O6, PBLN, LiGaO3, LiGeO3, TiGeO3, PbTiO3, PbZrO3, PVDF, etc. The piezoelectric layer 12 in the present embodiment may be one of the piezoelectric materials described above, or may be a stack of the above piezoelectric materials. A thickness of the piezoelectric layer 12 is in a range of 10 nm to 100 μm.

A material of the first base substrate 10 is preferably glass, and may alternatively be Si, sapphire, SiC, GaAs, GaN, InP, BN, ZnO, etc. A thickness of the first base substrate 10 is in a range of 0.1 μm to 10 mm.

A material of the first electrode 11 is preferably metal Cu, which has a lattice size is very close to that of the hexagonal phase boron nitride (hBN). Alternatively, the material of the first electrode 11 may be Al, Mo, Co, Ag, Ti, Pt, Ru, W, Au, or an alloy material of any of the above metals. A thickness of the first electrode 11 is in a range of 1 nm to 10 μm.

A material of the second electrode 13 may be selected from Cu, Al, Mo, Co, Ag, Ti, Pt, Ru, W, Au, or an alloy material of any of the above metals. A thickness of the second electrode 13 is in a range of 1 nm to 10 μm.

A material of the encapsulation layer 16 is preferably an organic compound capable of blocking moisture and oxygen, such as polyimide, epoxy, or the like. Alternatively, the material of the encapsulation layer 16 may be an inorganic material such as SiNₓ, Al₂O₃, or the like. The encapsulation layer 16 may be a single layer of material or may be a stack of materials.

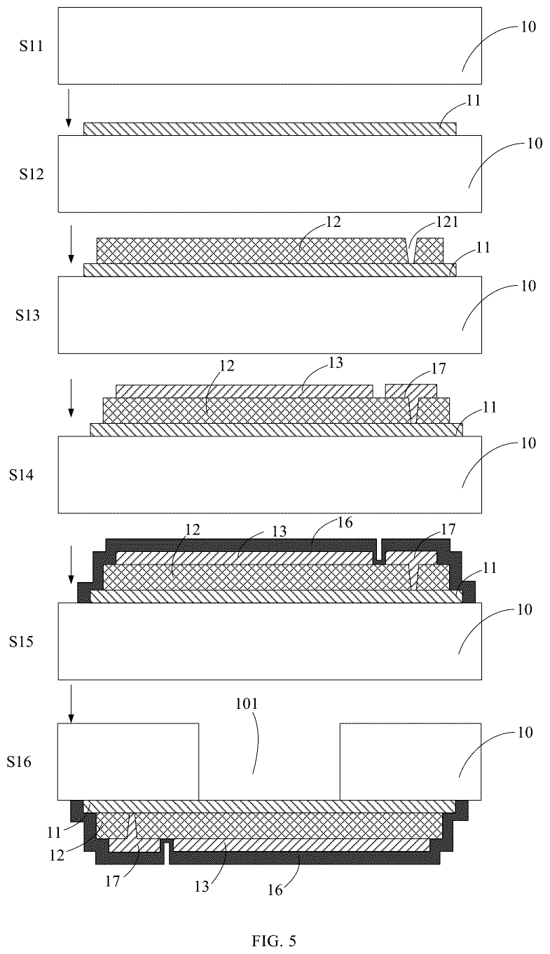

For the bulk acoustic wave resonator shown in FIG. 4, an embodiment of the present disclosure provides a method for manufacturing a bulk acoustic wave resonator. FIG. 5 is a flow chart of manufacturing a bulk acoustic wave resonator shown in FIG. 4. As shown in FIG. 5, the manufacturing method may specifically include the following steps:

S11, providing a first base substrate 10.

In this step, the first base substrate 10 may be cleaned and then dried by air knife.

S12, forming a first electrode 11 on the first base substrate 10.

In some examples, the step S12 may include depositing a first conductive film on the first base substrate 10, preferably by direct current magnetron sputtering (alternatively, radio frequency magnetron sputtering), alternatively by pulsed laser sputtering (PLD), molecular beam epitaxy (MBE), thermal evaporation, electron beam evaporation, or by attaching a copper foil. Processes including coating glue (or spraying glue), pre-baking, exposing, developing and post-baking are performed on the first conductive film. Finally, an etching process is performed, preferably a wet etching process, or alternatively a dry etching process, to form a pattern including the first electrode 11.

S13, forming a piezoelectric layer 12 on the first base substrate 10 after the above steps.

In some examples, as an example, a material of the piezoelectric layer 12 is hBN, in step S13, an orientation growth of the piezoelectric material may be performed firstly, preferably by radio frequency magnetron sputtering, and a target material is hBN. A hBN oriented film rich in nitrogen vacancies (whose the piezoelectric property is much better than that of BN without nitrogen vacancies) is formed by controlling an air pressure and a temperature of Ar and N2 and a time and temperature of post-annealing in the deposition, and preferably the growth orientation is (100), and may alternatively be (001) and (111). The film deposition method may be selected from pulsed laser sputtering (PLD), molecular beam epitaxy (MBE), metal organic chemical vapor deposition (MOCVD), plasma enhanced chemical vapor deposition (PECVD), and the like. The piezoelectric layer 12 is subjected to a photolithography process including coating glue (or spraying glue), pre-baking, exposing, developing and post-baking. Finally, the piezoelectric material layer is etched to form a pattern of the piezoelectric layer 12 with a first connecting via 121: a preferred etching process may be a wet etching process or a dry etching process.

S14, forming a second electrode 13 and a first connecting electrode 17 on the first base substrate 10 after the above steps.

In some examples, step S14 may include depositing a second conductive film, preferably by direct current magnetron sputtering (alternatively, radio frequency magnetron sputtering), alternatively by pulsed laser sputtering (PLD), molecular beam epitaxy (MBE), thermal evaporation, electron beam evaporation. Processes including coating glue (or spraying glue), pre-baking, exposing, developing and post-baking are performed on the second conductive film. Finally, an etching process is performed, preferably a wet etching process, or alternatively a dry etching process, to form the second electrode 13 and the first connecting electrode 17. The second conductive film formed on a hole wall is thinner, which is not favorable for low-loss transmission of radio frequency signals, so that the second conductive film in the first connecting via 121 may be thickened by an electroplating process, and then patterns of the second electrode 13 and the first connecting electrode 17 are formed.

S15, forming an encapsulation layer 16 on the first base substrate 10 after the above steps.

In some examples, a material of the encapsulation layer 16 may be an organic material polyimide. In this case, step S15 may include performing liquid coating of the organic material, such as spin coating, spraying, ink-jet printing, or transferring or the like, and then performing a heat curing process to form a pattern of the encapsulation layer 16.

S16, turning over the first base substrate 10 to form a first cavity 101 after the above steps.

In some examples, the first base substrate 10 may be a glass substrate, in which case, the step S16 may include forming the first cavity 101 penetrating through the first base substrate 10 in a thickness direction of the first base substrate 10 by bombarding the first base substrate 10 using a laser-induced method and then HF etching. The first cavity 101 has a cross-section which is substantially perpendicular to the glass surface at an angle of approximately 90°. The first cavity 101 may be formed by wet etching or dry etching for other non-glass substrates.

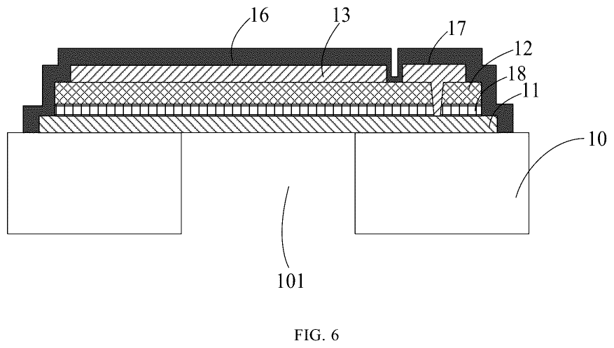

In a second example, FIG. 6 is a schematic diagram of a bulk acoustic wave resonator of the second example of an embodiment of the present disclosure. As shown in FIG. 6, the bulk acoustic wave resonator includes a first base substrate 10, and a first electrode 11, an inducing layer 18, a piezoelectric layer 12, and a second electrode 13 sequentially disposed on the first base substrate 10. An encapsulation layer 16 may also be provided on a side of the second electrode 13 away from the first base substrate 10. The first base substrate 10 is provided with a first cavity 101 penetrating through the first base substrate 10 in a thickness direction of the first base substrate 10. The first base substrate 10 includes a first surface (upper surface) and a second surface (lower surface) which are oppositely disposed in a thickness direction of the first base substrate 10, and the first cavity 101 includes a first opening formed in the first surface and a second opening formed in the second surface. The first electrode 11 is disposed on the first surface, and an orthographic projection of the first electrode 11 on a plane of the second surface covers an orthographic projection of the first opening on the plane of the second surface.

Further, in addition to the above structure, the bulk acoustic wave resonator further includes a first connecting electrode 17 disposed in the same layer as the second electrode 13, and connected to the first electrode 11 through a via penetrating through the piezoelectric layer 12. In this case, a radio frequency signal enters into the resonator from an upper left corner of FIG. 6, then is converted into an acoustic wave signal through an inverse piezoelectric effect at an interface between the second electrode 13 and the piezoelectric layer 12, and the acoustic wave signal is longitudinally transmitted in the piezoelectric layer 12, and is converted into a radio frequency signal through the piezoelectric effect at an interface among the first electrode 11, the inducing layer 18 and the piezoelectric layer 12, and is transmitted upward through a conductive through hole at the lower right corner of the first electrode 11, and finally is transmitted outward at the upper right corner of the second electrode 13. The first cavity 101 below the resonator and the air layer above the resonator together act as an acoustic reflector, and are configured to confine the acoustic signal within the resonator structure rather than dissipating the acoustic signal out, thereby reducing the losses of the resonator.

In this example, a material of the piezoelectric layer 12 is preferably hBN, and may alternatively be cBN, wBN. Alternatively, the material of the piezoelectric layer 12 may be selected from AlN, ZnO, PZT, GaN, InN, CdS, CdSe, ZnS, CdTe, ZnTe, GaAs, GaSb, InAs, InSb, GaSe, GaP, AlP, quartz crystal, LiTaO3, LiNbO3, La3Ga5SiO14, BaTiO3, PbNb2O6, PBLN, LiGaO3, LiGeO3, TiGeO3, PbTiO3, PbZrO3, PVDF, etc. The piezoelectric layer 12 in the present embodiment may be one of the piezoelectric materials described above, or may be a stack of the above piezoelectric materials. A thickness of the piezoelectric layer 12 is in a range of 10 nm to 100 μm.

A material of the first base substrate 10 is preferably glass, and may alternatively be Si, sapphire, SiC, GaAs, GaN, InP, BN, ZnO, etc. A thickness of the first base substrate 10 is in a range of 0.1 μm to 10 mm.

A material of the first electrode 11 is preferably metal Cu, which has a lattice size is very close to that of the hexagonal phase boron nitride (hBN). Alternatively, the material of the first electrode 11 may be Al, Mo, Co, Ag, Ti, Pt, Ru, W, Au, or an alloy material of any of the above metals. A thickness of the first electrode 11 is in a range of 1 nm to 10 μm.

The inducing layer 18 is located between the first electrode 11 and the piezoelectric layer 12, and configured to assist the growth of the piezoelectric layer 12, so that an orientation of the piezoelectric layer 12 is C-axis orientation (an acoustic velocity of the piezoelectric layer 12 along a C axis is the highest), and a quality of the material of the piezoelectric layer 12 is improved (for example, a full width at half maximum of a rocking curve of X-ray diffraction is less than) 1.5°. In this embodiment, the inducing layer 18 is preferably made of graphene, and may be single-layer graphene, or may be double-layer graphene or multi-layer graphene. That is, a thickness of the inducing layer 18 is in a range of 0.1 nm to 100 nm.

A material of the second electrode 13 may be selected from Cu, Al, Mo, Co, Ag, Ti, Pt, Ru, W, Au, or an alloy material of any of the above metals. A thickness of the second electrode 13 is in a range of 1 nm to 10 μm.

A material of the encapsulation layer 16 is preferably an organic compound capable of blocking moisture and oxygen, such as polyimide, epoxy, or the like. Alternatively, the material of the encapsulation layer 16 may be an inorganic material such as SiNₓ, Al₂O₃, or the like. The encapsulation layer 16 may be a single layer of material or may be a stack of materials.

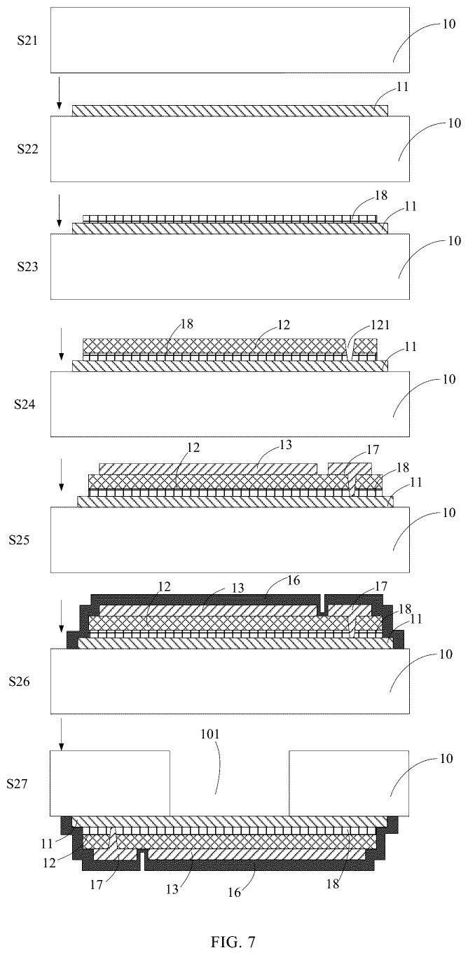

For the bulk acoustic wave resonator shown in FIG. 6, an embodiment of the present disclosure provides a method for manufacturing a bulk acoustic wave resonator. FIG. 7 is a flow chart of manufacturing a bulk acoustic wave resonator shown in FIG. 6. As shown in FIG. 7, the manufacturing method may specifically include the following steps:

S21, providing a first base substrate 10.

In this step, the first base substrate 10 may be cleaned and then dried by air knife.

S22, forming a first electrode 11 on the first base substrate 10.

In some examples, the step S22 may include depositing a first conductive film on the first base substrate 10, preferably by direct current magnetron sputtering (alternatively, radio frequency magnetron sputtering), alternatively by pulsed laser sputtering (PLD), molecular beam epitaxy (MBE), thermal evaporation, electron beam evaporation, or by attaching a copper foil. Processes including coating glue (or spraying glue), pre-baking, exposing, developing and post-baking are performed on the first conductive film. Finally, an etching process is performed, preferably a wet etching process, or alternatively a dry etching process, to form a pattern including the first electrode 11.

S23, forming an inducing layer 18 on the first base substrate 10 after the above steps.

In some examples, a material of the inducing layer 18 is preferably a graphene film, and may be single-layer, or may be double-layer or multi-layer. If the material of the first electrode 11 formed in step S22 is a metal, such as Fe, Ru, Co, Rh, Ir, Ni, Pd. Pt, Cu, Au, or an alloy, such as Co—Ni, Au—Ni, by taking the inducing layer 18 as the graphene material as an example, the graphene material may be directly grown by magnetron sputtering chemical vapor deposition or microwave plasma chemical vapor deposition, which specifically includes: introducing a mixed gas of methane, nitrogen and argon, and heating the substrate to 600° C. to 800° C., and generating the graphene film through a reaction. If the first electrode 11 formed in step S22 is not the above metal or alloy, the inducing layer may be formed in two steps: (a) the first step of forming the graphene film, including putting a metal foil, such as a foil of a metal, such as Fe, Ru, Co, Rh, Ir, Ni, Pd, Pt, Cu, Au or an alloy, such as Co—Ni, Au—Ni, into a reaction chamber: growing the graphene material by magnetron sputtering chemical vapor deposition or microwave plasma chemical vapor deposition, which specifically includes: introducing a mixed gas of methane, nitrogen and argon, and heating the substrate to 600° C. to 800° C., and generating the graphene film through a reaction: (b) the second step of transferring the formed graphene film from the metal foil to the first electrode 11, including firstly, spraying or spin-coating polymethyl methacrylate (PMMA) on the metal foil/graphene in an inert gas atmosphere, and heating the metal foil/graphene at 120° C. for 3 minutes to 5 minutes for drying and curing: putting the metal foil/graphene/PMMA into a corresponding solution to dissolve the metal away, for example, putting the copper foil into a 20% FeCl3 solution, wherein the rest graphene/PMMA is floating on the surface of the solution: taking out the graphene/PMMA from the solution, putting the graphene/PMMA into deionized water for cleaning, transferring the graphene/PMMA onto the first electrode 11; irradiating the graphene/PMMA for 10 minutes to 15 minutes by using an infrared lamp for drying; and finally dissolving the PMMA away by using an organic solvent such as acetone. The inducing layer 18 has been formed.

S24, forming a piezoelectric layer 12 on the first base substrate 10 after the above steps.

In some examples, as an example, a material of the piezoelectric layer 12 is hBN, in step S24, an orientation growth of the piezoelectric material may be performed firstly, preferably by radio frequency magnetron sputtering, and a target material is hBN. A hBN oriented film rich in nitrogen vacancies (whose the piezoelectric property is much better than that of BN without nitrogen vacancies) is formed by controlling an air pressure and a temperature of Ar and N2 and a time and temperature of post-annealing in the deposition, and preferably the growth orientation is (100), and may alternatively be (001) and (111). The film deposition method may be selected from pulsed laser sputtering (PLD), molecular beam epitaxy (MBE), metal organic chemical vapor deposition (MOCVD), plasma enhanced chemical vapor deposition (PECVD), and the like. The piezoelectric layer 12 is subjected to a photolithography process including coating glue (or spraying glue), pre-baking, exposing, developing and post-baking. Finally, the piezoelectric material layer and the inducing layer 18 are etched to form a first connecting via 121: a preferred etching process may be a wet etching process or a dry etching process.

S25, forming a second electrode 13 and a first connecting electrode 17 on the first base substrate 10 after the above steps.

In some examples, step S25 may include depositing a second conductive film, preferably by direct current magnetron sputtering (alternatively by radio frequency magnetron sputtering), alternatively by pulsed laser sputtering (PLD), molecular beam epitaxy (MBE), thermal evaporation, electron beam evaporation. Processes including coating glue (or spraying glue), pre-baking, exposing, developing and post-baking are performed on the second conductive film. Finally, an etching process is performed, preferably a wet etching process, or alternatively a dry etching process, to form the second electrode 13 and the first connecting electrode 17. The second conductive film formed on a hole wall is thinner, which is not favorable for low-loss transmission of radio frequency signals, so that the second conductive film in the first connecting via 121 may be thickened by an electroplating process, and then patterns of the second electrode 13 and the first connecting electrode 17 are formed.

S26, forming an encapsulation layer 16 on the first base substrate 10 after the above steps.

In some examples, a material of the encapsulation layer 16 may be an organic material polyimide. In this case, step S26 may include performing liquid coating of the organic material, such as spin coating, spraying, ink-jet printing, or transferring or the like, and then performing a heat curing process to form a pattern of the encapsulation layer 16.

S27, turning over the first base substrate 10 to form a first cavity 101 after the above steps.

In some examples, the first base substrate 10 may be a glass substrate, in which case, the step S27 may include forming the first cavity 101 penetrating through the first base substrate 10 in a thickness direction of the first base substrate 10 by bombarding the first base substrate 10 using a laser-induced method and then HF etching. The first cavity 101 has a cross-section which is substantially perpendicular to the glass surface at an angle of approximately 90°. The first cavity 101 may be formed by wet etching or dry etching for other non-glass substrates.

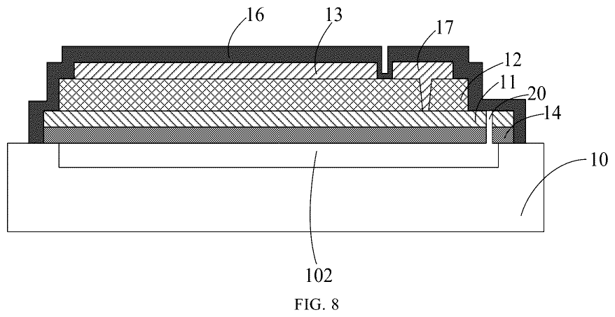

In a third example, FIG. 8 is a schematic diagram of a bulk acoustic wave resonator of the third example of an embodiment of the present disclosure. As shown in FIG. 8, the bulk acoustic wave resonator includes a first base substrate 10, and an isolation layer 14, a first electrode 11, a piezoelectric layer 12, and a second electrode 13 sequentially disposed on the first base substrate 10. An encapsulation layer 16 may also be provided on a side of the second electrode 13 away from the first base substrate 10. The first base substrate 10 is provided with a first groove 102. The first base substrate 10 includes a first surface (upper surface) and a second surface (lower surface) which are oppositely disposed in a thickness direction of the first base substrate 10, and a third opening of the first groove 102 is located in the first surface. The first electrode 11 is disposed on the first surface, and an orthographic projection of the first electrode 11 on a plane of the second surface covers an orthographic projection of the third opening on the plane of the second surface.

Further, in addition to the above structure, the bulk acoustic wave resonator further includes a first connecting electrode 17 disposed in the same layer as the second electrode 13, and connected to the first electrode 11 through a via penetrating through the piezoelectric layer 12. In this case, a radio frequency signal enters into the resonator from an upper left corner of FIG. 8, then is converted into an acoustic wave signal through an inverse piezoelectric effect at an interface between the second electrode 13 and the piezoelectric layer 12, and the acoustic wave signal is longitudinally transmitted in the piezoelectric layer 12, and is converted into a radio frequency signal through the piezoelectric effect at an interface between the first electrode 11 and the piezoelectric layer 12, and is transmitted upward through a conductive through hole at the lower right corner of the first electrode 11, and finally is transmitted outward at the upper right corner of the second electrode 13. The first groove 102 below the resonator and the air layer above the resonator together act as an acoustic reflector, and are configured to confine the acoustic signal within the resonator structure rather than dissipating the acoustic signal out, thereby reducing the losses of the resonator.

In this example, a material of the piezoelectric layer 12 is preferably hBN, and may alternatively be cBN, wBN. Alternatively, the material of the piezoelectric layer 12 may be selected from AlN, ZnO, PZT, GaN, InN, CdS, CdSe, ZnS, CdTe, ZnTe, GaAs, GaSb, InAs, InSb, GaSe, GaP, AlP, quartz crystal, LiTaO3, LiNbO3, La3Ga5SiO14, BaTiO3, PbNb2O6, PBLN, LiGaO3, LiGeO3, TiGeO3, PbTiO3, PbZrO3, PVDF, etc. The piezoelectric layer 12 in the present embodiment may be one of the piezoelectric materials described above, or may be a stack of the above piezoelectric materials. A thickness of the piezoelectric layer 12 is in a range of 10 nm to 100 μm.

A material of the first base substrate 10 is preferably glass, and may alternatively be Si, sapphire, SiC, GaAs, GaN, InP, BN, ZnO, etc. A thickness of the first base substrate 10 is in a range of 0.1 μm to 10 mm.

The isolation layer 14 is configured to electrically isolate the first groove 102 from the bulk acoustic wave resonator and provide a support for the structure, and may be made of an insulating material, such as SiO₂, Si₃N₄, Al₂O₃, and a stack thereof. A thickness of the isolation layer 14 is in a range of 1 nm to 100 μm.

A material of the first electrode 11 is preferably metal Cu, which has a lattice size is very close to that of the hexagonal phase boron nitride (hBN). Alternatively, the material of the first electrode 11 may be Al, Mo, Co, Ag, Ti, Pt, Ru, W, Au, or an alloy material of any of the above metals. A thickness of the first electrode 11 is in a range of 1 nm to 10 μm.

A material of the second electrode 13 may be selected from Cu, Al, Mo, Co, Ag, Ti, Pt, Ru, W, Au, or an alloy material of any of the above metals. A thickness of the second electrode 13 is in a range of 1 nm to 10 μm.

A material of the encapsulation layer 16 is preferably an organic compound capable of blocking moisture and oxygen, such as polyimide, epoxy, or the like.

Alternatively, the material of the encapsulation layer 16 may be an inorganic material such as SiNₓ, Al₂O₃, or the like. The encapsulation layer 16 may be a single layer of material or may be a stack of materials.

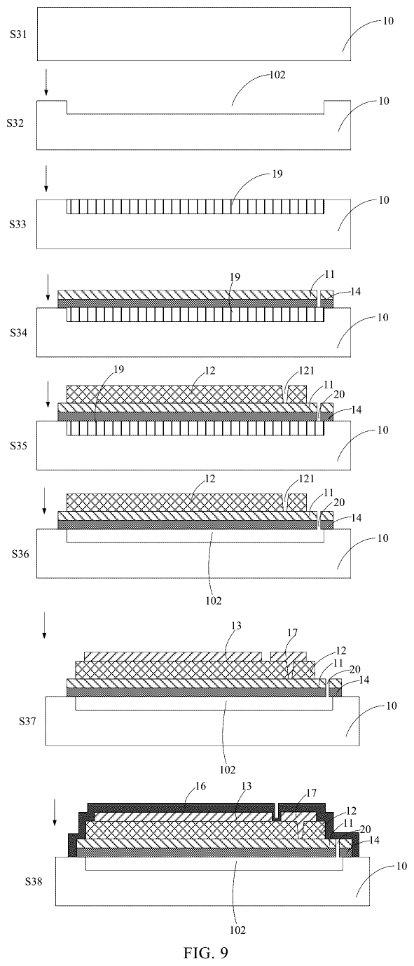

For the bulk acoustic wave resonator shown in FIG. 8, an embodiment of the present disclosure provides a method for manufacturing a bulk acoustic wave resonator. FIG. 9 is a flow chart of manufacturing a bulk acoustic wave resonator shown in FIG. 8. As shown in FIG. 9, the manufacturing method may specifically include the following steps:

S31, providing a first base substrate 10.

In this step, the first base substrate 10 may be cleaned and then dried by air knife.

S32, forming a first groove 102 in the first base substrate 10.

In some examples, step S32 may include depositing a mask material (optionally, the mask material may be a photoresist, an inorganic mask, or a metal mask) on the first base substrate 10, then performing processes including coating glue (or spraying glue), pre-baking, exposing, developing and post-baking, and finally performing an etching process to form a mask, wherein the etching process is preferably a wet etching process, or alternatively a dry etching process. Next, the first base substrate 10 is etched to form the first groove 102. The etching process is preferably a wet etching process, or alternatively a dry etching process. For example: the first base substrate 10 adopts a glass substrate, and the etching solution adopted at this time is a mixed solution of 3% to 7% of hydrofluoric acid, 20% to 30% of ammonium fluoride and deionized water.

S33, forming a filling structure 19 in the first groove 102, so that the first groove 102 is filled and surfaces of the filling structure 19 and the first groove 102 are flush with each other.

In this step, in order to ensure that the subsequent processes may be performed smoothly, the first groove 102 formed in step S32 is firstly filled. A material of the filling structure 19 is preferably loose silicon dioxide doped with boron and phosphorus. In some examples, the step S33 may include performing processes, including plasma enhanced chemical vapor deposition (PECVD), sub-atmospheric pressure chemical vapor deposition (SACVD) and screen printing, on the slurry containing the loose silicon dioxide doped with boron and phosphorus, performing a thermal annealing process at 700° C. to 900° C., so that the loose silicon dioxide doped with boron and phosphorus is liquefied and flows, and completely fills pores in the first groove 102 and then is cooled down and cured. Then, portions of the silicon dioxide film doped with boron and phosphorus above the substrate surface are removed and the first surface of the first base substrate 10 is polished through an electrochemical mechanical polishing (CMP) process.

S34, forming an isolation layer 14 and a first electrode 11 on the first base substrate 10, and forming a first through hole 20 penetrating through the isolation layer 14 and the first electrode 11 after the above steps.

In some examples, step S34 may include: firstly depositing an electrical insulating material by radio frequency magnetron sputtering, pulsed laser sputtering (PLD), atomic layer deposition (ALD) or plasma enhanced chemical vapor deposition (PECVD); and then performing processes including coating glue (or spraying glue), pre-baking, exposing, developing, post-baking and etching, to form the isolation layer 14. The etching process may be a wet etching process, or a dry etching process.

Next, a first conductive film is formed on a side of the isolation layer 14 away from the first base substrate 10, preferably by direct current magnetron sputtering (alternatively, radio frequency magnetron sputtering), alternatively by pulsed laser sputtering (PLD), molecular beam epitaxy (MBE), thermal evaporation, electron beam evaporation, or by attaching a copper foil. Processes including coating glue (or spraying glue), pre-baking, exposing, developing and post-baking are performed on the first conductive film. Finally, an etching process is performed, preferably a wet etching process, or alternatively a dry etching process, to form a pattern including the first electrode 11.

Finally, the isolation layer 14 and the first electrode 11 are etched to form the first through hole 20, where one or more first through holes 20 may be included. In the embodiment of the present disclosure, preferably, a plurality of the first through holes 20 are included. Specifically, processes including coating glue (or spraying glue), pre-baking, exposing, developing and post-baking may be performed on a side of the first electrode 11 away from the first base substrate 10, and then a dry etching process is performed on the first electrode 11, and then the etching gas is replaced to etch the isolation layer 14, until the isolation layer is etched on a filling material layer.

S36, forming a piezoelectric layer 12 on the first base substrate 10 after the above steps.

In some examples, as an example, a material of the piezoelectric layer 12 is hBN, in step S36, an orientation growth of the piezoelectric material may be performed firstly, preferably by radio frequency magnetron sputtering, and a target material is hBN. A hBN oriented film rich in nitrogen vacancies (whose the piezoelectric property is much better than that of BN without nitrogen vacancies) is formed by controlling an air pressure and a temperature of Ar and N2 and a time and temperature of post-annealing in the deposition, and preferably the growth orientation is (100), and may alternatively be (001) and (111). The film deposition method may be selected from pulsed laser sputtering (PLD), molecular beam epitaxy (MBE), metal organic chemical vapor deposition (MOCVD), plasma enhanced chemical vapor deposition (PECVD), and the like. The piezoelectric layer 12 is subjected to a photolithography process including coating glue (or spraying glue), pre-baking, exposing, developing and post-baking. Finally, the piezoelectric material layer is etched to form a pattern of the piezoelectric layer 12 including a first connecting via 121: a preferred etching process may be a wet etching process or a dry etching process.

S37, forming a second electrode 13 and a first connecting electrode 17 on the first base substrate 10 after the above steps.

In some examples, step S37 may include depositing a second conductive film, preferably by direct current magnetron sputtering (alternatively, radio frequency magnetron sputtering), alternatively by pulsed laser sputtering (PLD), molecular beam epitaxy (MBE), thermal evaporation, electron beam evaporation. Processes including coating glue (or spraying glue), pre-baking, exposing, developing and post-baking are performed on the second conductive film. Finally, an etching process is performed, preferably a wet etching process, or alternatively a dry etching process, to form the second electrode 13 and the first connecting electrode 17. The second conductive film formed on a hole wall is thinner, which is not favorable for low-loss transmission of radio frequency signals, so that the second conductive film in the first connecting via 121 may be thickened by an electroplating process, and then patterns of the second electrode 13 and the first connecting electrode 17 are formed.

S38, removing the filling structure 19.

In some examples, step S38 may include performing a dip etching using a mixed etching solution of hydrofluoric acid and nitric acid, so that the loose silicon dioxide doped with boron and phosphorus as the filling material in the first groove 102 is completely dissolved away over enough time; and finally cleaning the first groove 102 with a deionized water, and baking the first groove 102.

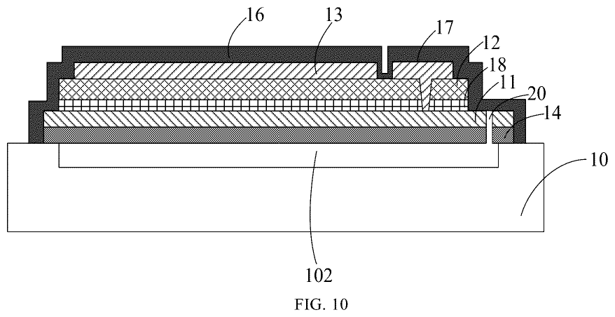

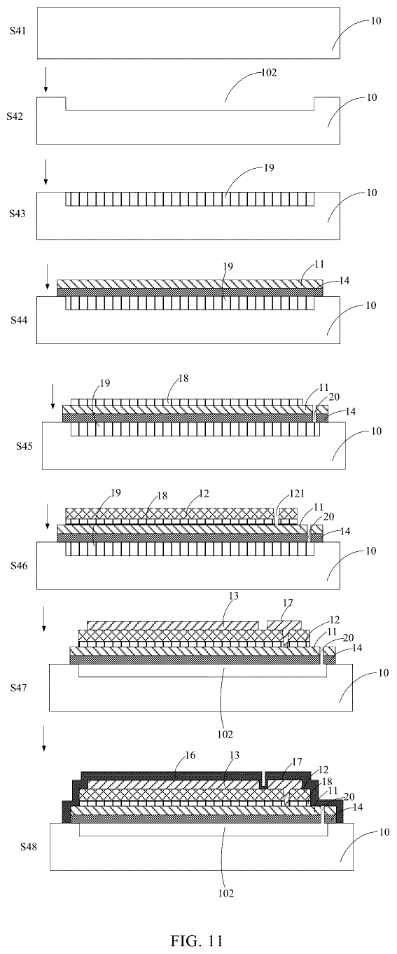

In a fourth example, FIG. 10 is a schematic diagram of a bulk acoustic wave resonator of a fourth example of an embodiment of the present disclosure. As shown in FIG. 10, the bulk acoustic wave resonator includes a first base substrate 10, and an isolation layer 14, a first electrode 11, an inducing layer 18, a piezoelectric layer 12, and a second electrode 13 sequentially disposed on the first base substrate 10. An encapsulation layer 16 may also be provided on a side of the second electrode 13 away from the first base substrate 10. The first base substrate 10 is provided with a first groove 102. The first base substrate 10 includes a first surface (upper surface) and a second surface (lower surface) which are oppositely disposed in a thickness direction of the first base substrate 10, and a third opening of the first groove 102 is located in the first surface. The first electrode 11 is disposed on the first surface, and an orthographic projection of the first electrode 11 on a plane of the second surface covers an orthographic projection of the third opening on the plane of the second surface.

Further, in addition to the above structure, the bulk acoustic wave resonator further includes a first connecting electrode 17 disposed in the same layer as the second electrode 13, and connected to the first electrode 11 through a via penetrating through the piezoelectric layer 12. In this case, a radio frequency signal enters into the resonator from an upper left corner of FIG. 10, then is converted into an acoustic wave signal through an inverse piezoelectric effect at an interface between the second electrode 13 and the piezoelectric layer 12, and the acoustic wave signal is longitudinally transmitted in the piezoelectric layer 12, and is converted into a radio frequency signal through the piezoelectric effect at an interface among the first electrode 11, the inducing layer 18 and the piezoelectric layer 12, and is transmitted upward through a conductive through hole at the lower right corner of the first electrode 11, and finally is transmitted outward at the upper right corner of the second electrode 13. The first cavity 101 below the resonator and the air layer above the resonator together act as an acoustic reflector, and are configured to confine the acoustic signal within the resonator structure rather than dissipating the acoustic signal out, thereby reducing the losses of the resonator.

In this example, a material of the piezoelectric layer 12 is preferably hBN, and may alternatively be cBN, wBN. Alternatively, the material of the piezoelectric layer 12 may be selected from AlN, ZnO, PZT, GaN, InN, CdS, CdSe, ZnS, CdTe, ZnTe, GaAs, GaSb. InAs, InSb, GaSe, GaP, AlP, quartz crystal, LiTaO3, LiNbO3, La3Ga5SiO14, BaTiO3, PbNb2O6, PBLN, LiGaO3, LiGeO3, TiGeO3, PbTiO3, PbZrO3, PVDF, etc. The piezoelectric layer 12 in the present embodiment may be one of the piezoelectric materials described above, or may be a stack of the above piezoelectric materials. A thickness of the piezoelectric layer 12 is in a range of 10 nm to 100 μm.

A material of the first base substrate 10 is preferably glass, and may alternatively be Si, sapphire, SiC, GaAs, GaN, InP, BN, ZnO, etc. A thickness of the first base substrate 10 is in a range of 0.1 μm to 10 mm.

The isolation layer 14 is configured to electrically isolate the first groove 102 from the bulk acoustic wave resonator and provide a support for the structure, and may be made of an insulating material, such as SiO₂, Si₃N₄, Al₂O₃, and a stack thereof. A thickness of the isolation layer 14 is in a range of 1 nm to 100 μm.

A material of the first electrode 11 is preferably metal Cu, which has a lattice size is very close to that of the hexagonal phase boron nitride (hBN). Alternatively, the material of the first electrode 11 may be Al, Mo, Co, Ag, Ti, Pt, Ru, W, Au, or an alloy material of any of the above metals. A thickness of the first electrode 11 is in a range of 1 nm to 10 μm.

The inducing layer 18 is located between the first electrode 11 and the piezoelectric layer 12, and is configured to assist the growth of the piezoelectric layer 12, so that an orientation of the piezoelectric layer 12 is C-axis orientation (an acoustic velocity of the piezoelectric layer 12 along a C axis is the highest), and a quality of the material of the piezoelectric layer 12 is improved (for example, a full width at half maximum of a rocking curve of X-ray diffraction is less than) 1.5°. In this embodiment, the inducing layer 18 is preferably made of graphene, and may be single-layer graphene, or may be double-layer graphene or multi-layer graphene. That is, a thickness of the inducing layer 18 is in a range of 0.1 nm to 100 nm.

A material of the second electrode 13 may be selected from Cu, Al, Mo, Co, Ag, Ti, Pt, Ru, W, Au, or an alloy material of any of the above metals. A thickness of the second electrode 13 is in a range of 1 nm to 10 μm.

A material of the encapsulation layer 16 is preferably an organic compound capable of blocking moisture and oxygen, such as polyimide, epoxy, or the like. Alternatively, the material of the encapsulation layer 16 may be an inorganic material such as SiNₓ, Al₂O₃, or the like. The encapsulation layer 16 may be a single layer of material or may be a stack of materials.

For the bulk acoustic wave resonator shown in FIG. 10, an embodiment of the present disclosure provides a method for manufacturing a bulk acoustic wave resonator. FIG. 11 is a flow chart of manufacturing a bulk acoustic wave resonator shown in FIG. 10. As shown in FIG. 11, the manufacturing method may specifically include the following steps:

S41, providing a first base substrate 10.

In this step, the first base substrate 10 may be cleaned and then dried by air knife.

S42, forming a first groove 102 in the first base substrate 10.

In some examples, step S42 may include depositing a mask material (optionally, the mask material may be a photoresist, an inorganic mask, or a metal mask) on the first base substrate 10, then performing processes including coating glue (or spraying glue), pre-baking, exposing, developing and post-baking, and finally performing an etching process to form a mask, wherein the etching process is preferably a wet etching process, or alternatively a dry etching process. Next, the first base substrate 10 is etched to form the first groove 102. The etching process is preferably a wet etching process, or alternatively a dry etching process. For example: the first base substrate 10 adopts a glass substrate, and the etching solution adopted at this time is a mixed solution of 3% to 7% of hydrofluoric acid, 20% to 30% of ammonium fluoride and deionized water.

S43, forming a filling structure 19 in the first groove 102, so that the first groove 102 is filled and surfaces of the filling structure 19 and the first groove 102 are flush with each other.

In this step, in order to ensure that the subsequent processes may be performed smoothly, the first groove 102 formed in step S42 is firstly filled. A material of the filling structure 19 is preferably loose silicon dioxide doped with boron and phosphorus. In some examples, the step S43 may include performing processes, including plasma enhanced chemical vapor deposition (PECVD), sub-atmospheric pressure chemical vapor deposition (SACVD) and screen printing, on the slurry containing the loose silicon dioxide doped with boron and phosphorus, performing a thermal annealing process at 700° C. to 900° C., so that the loose silicon dioxide doped with boron and phosphorus is liquefied and flows, and completely fills pores in the first groove 102 and then is cooled down and cured. Then, portions of the silicon dioxide film doped with boron and phosphorus above the substrate surface are removed and the first surface of the first base substrate 10 is polished through an electrochemical mechanical polishing (CMP) process.

S44, forming an isolation layer 14 and a first electrode 11 on the first base substrate 10 after the above steps.

In some examples, step S44 may include: firstly depositing an electrical insulating material by radio frequency magnetron sputtering, pulsed laser sputtering (PLD), atomic layer deposition (ALD) or plasma enhanced chemical vapor deposition (PECVD); and then performing processes including coating glue (or spraying glue), pre-baking, exposing, developing, post-baking and etching, to form the isolation layer 14. The etching process may be a wet etching process, or a dry etching process.

Next, a first conductive film is formed on a side of the isolation layer 14 away from the first base substrate 10, preferably by direct current magnetron sputtering (alternatively, radio frequency magnetron sputtering), alternatively by pulsed laser sputtering (PLD), molecular beam epitaxy (MBE), thermal evaporation, electron beam evaporation, or by attaching a copper foil. Processes including coating glue (or spraying glue), pre-baking, exposing, developing and post-baking are performed on the first conductive film. Finally, an etching process is performed, preferably a wet etching process, or alternatively a dry etching process, to form a pattern including the first electrode 11.

S45, forming an inducing layer 18 on the first base substrate 10, and etching the isolation layer 14 and the first electrode 11 to form a first through hole 20 after the above steps are completed.

In some examples, a material of the inducing layer 18 is preferably a graphene film, and may be single-layer, or may be double-layer or multi-layer. If the material of the first electrode 11 formed in step S22 is a metal, such as Fe, Ru, Co, Rh, Ir, Ni, Pd, Pt, Cu, Au, or an alloy, such as Co—Ni, Au—Ni, by taking the inducing layer 18 as the graphene material as an example, the graphene material may be directly grown by magnetron sputtering chemical vapor deposition or microwave plasma chemical vapor deposition, which specifically includes: introducing a mixed gas of methane, nitrogen and argon, and heating the substrate to 600° C. to 800° C., and generating the graphene film through a reaction. If the first electrode 11 formed in step S44 is not the above metal or alloy, the inducing layer may be formed in two steps: (a) the first step of forming the graphene film, including putting a metal foil, such as a foil of a metal, such as Fe, Ru, Co, Rh, Ir, Ni, Pd, Pt, Cu, Au or an alloy, such as Co—Ni, Au—Ni, into a reaction chamber: growing the graphene material by magnetron sputtering chemical vapor deposition or microwave plasma chemical vapor deposition, which specifically includes: introducing a mixed gas of methane, nitrogen and argon, and heating the substrate to 600° C. to 800° C., and generating the graphene film through a reaction: (b) the second step of transferring the formed graphene film from the metal foil to the first electrode 11, including firstly, spraying or spin-coating polymethyl methacrylate (PMMA) on the metal foil/graphene in an inert gas atmosphere, and heating the metal foil/graphene at 120° C. for 3 minutes to 5 minutes for drying and curing: putting the metal foil/graphene/PMMA into a corresponding solution to dissolve the metal away, for example, putting the copper foil into a 20% FeCl3 solution, wherein the rest graphene/PMMA is floating on the surface of the solution: taking out the graphene/PMMA from the solution, putting the graphene/PMMA into deionized water for cleaning, transferring the graphene/PMMA onto the first electrode 11; irradiating the graphene/PMMA for 10 minutes to 15 minutes by using an infrared lamp for drying; and finally dissolving the PMMA away by using an organic solvent such as acetone. The inducing layer 18 has been formed.

Finally, the isolation layer 14 and the first electrode 11 on the first base substrate 10 are etched to form the first through hole 20.

One or more first through holes 20 may be included. In the embodiment of the present disclosure, preferably, a plurality of the first through holes 20 are included. In some examples, step S37 may include: performing processes including coating glue (or spraying glue), pre-baking, exposing, developing and post-baking on a side of the first electrode 11 away from the first base substrate 10, and then performing a dry etching process on the first electrode 11, and then replacing the etching gas to etch the isolation layer 14, until the isolation layer is etched on a filling material layer.

S46, forming a piezoelectric layer 12 on the first base substrate 10 after the above steps.

In some examples, as an example, a material of the piezoelectric layer 12 is hBN, in step S46, an orientation growth of the piezoelectric material may be performed firstly, preferably by radio frequency magnetron sputtering, and a target material is hBN. A hBN oriented film rich in nitrogen vacancies (whose the piezoelectric property is much better than that of BN without nitrogen vacancies) is formed by controlling an air pressure and a temperature of Ar and N2 and a time and temperature of post-annealing in the deposition, and preferably the growth orientation is (100), and may alternatively be (001) and (111). The film deposition method may be selected from pulsed laser sputtering (PLD), molecular beam epitaxy (MBE), metal organic chemical vapor deposition (MOCVD), plasma enhanced chemical vapor deposition (PECVD), and the like. The piezoelectric layer 12 is subjected to a photolithography process including coating glue (or spraying glue), pre-baking, exposing, developing and post-baking. Finally, the piezoelectric material layer is etched to form a pattern of the piezoelectric layer 12 including a first connecting via 121: a preferred etching process may be a wet etching process or a dry etching process.

S47, forming a second electrode 13 and a first connecting electrode 17 on the first base substrate 10 after the above steps.

In some examples, step S47 may include depositing a second conductive film, preferably by direct current magnetron sputtering (alternatively, radio frequency magnetron sputtering), alternatively by pulsed laser sputtering (PLD), molecular beam epitaxy (MBE), thermal evaporation, electron beam evaporation. Processes including coating glue (or spraying glue), pre-baking, exposing, developing and post-baking are performed on the second conductive film. Finally, an etching process is performed, preferably a wet etching process, or alternatively a dry etching process, to form the second electrode 13 and the first connecting electrode 17. The second conductive film formed on a hole wall is thinner, which is not favorable for low-loss transmission of radio frequency signals, so that the second conductive film in the first connecting via 121 may be thickened by an electroplating process, and then patterns of the second electrode 13 and the first connecting electrode 17 are formed.

S48, removing the filling structure 19.

In some examples, step S48 may include performing a dip etching using a mixed etching solution of hydrofluoric acid and nitric acid, so that the loose silicon dioxide doped with boron and phosphorus as the filling material in the first groove 102 is completely dissolved away over enough time; and finally cleaning the first groove 102 with a deionized water, and baking the first groove 102.

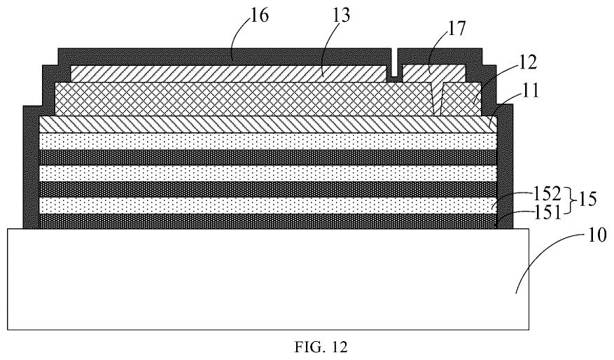

In a fifth example, FIG. 12 is a schematic diagram of a bulk acoustic wave resonator of a fifth example of an embodiment of the present disclosure. As shown in FIG. 12, the bulk acoustic wave resonator includes a first base substrate 10, and at least one acoustic mirror structure 15, a first electrode 11, a piezoelectric layer 12, and a second electrode 13 sequentially disposed on the first base substrate 10. An encapsulation layer 16 may also be provided on a side of the second electrode 13 away from the first base substrate 10. Each mirror structure 15 includes a first sub-structure and a second sub-structure sequentially arranged along a direction away from the first base substrate 10, and an acoustic impedance of a material of the first sub-structure is greater than that of a material of the second sub-structure. For ease of description and understanding, the first sub-structure will be referred to hereinafter as a high acoustic impedance layer 151 and the second sub-structure as a low acoustic impedance layer 152.

Further, in addition to the above structure, the bulk acoustic wave resonator further includes a first connecting electrode 17 disposed in the same layer as the second electrode 13, and connected to the first electrode 11 through a via penetrating through the piezoelectric layer 12. In this case, a radio frequency signal enters into the resonator from an upper left corner of FIG. 12, then is converted into an acoustic wave signal through an inverse piezoelectric effect at an interface between the second electrode 13 and the piezoelectric layer 12, and the acoustic wave signal is longitudinally transmitted in the piezoelectric layer 12, and is converted into a radio frequency signal through the piezoelectric effect at an interface between the first electrode 11 and the piezoelectric layer 12, and is transmitted upward through a conductive through hole at the lower right corner of the first electrode 11, and finally is transmitted outward at the upper right corner of the second electrode 13. The at least one acoustic mirror structure 15 below the resonator and the air layer above the resonator together act as an acoustic reflector, and are configured to confine the acoustic signal within the resonator structure rather than dissipating the acoustic signal out, thereby reducing the losses of the resonator.

In this example, a material of the piezoelectric layer 12 is preferably hBN, and may alternatively be cBN, wBN. Alternatively, the material of the piezoelectric layer 12 may be selected from AlN, ZnO, PZT, GaN, InN, CdS, CdSe, ZnS, CdTe, ZnTe, GaAs, GaSb, InAs, InSb, GaSe, GaP, AlP, quartz crystal, LiTaO3, LiNbO3, La3Ga5SiO14, BaTiO3, PbNb2O6, PBLN, LiGaO3, LiGeO3, TiGeO3, PbTiO3, PbZrO3, PVDF, etc. The piezoelectric layer 12 in the present embodiment may be one of the piezoelectric materials described above, or may be a stack of the above piezoelectric materials. A thickness of the piezoelectric layer 12 is in a range of 10 nm to 100 μm.

A material of the first base substrate 10 is preferably glass, and may alternatively be Si, sapphire, SiC, GaAs, GaN, InP, BN, ZnO, etc. A thickness of the first base substrate 10 is in a range of 0.1 μm to 10 mm.

The at least one acoustic mirror structure 15 is composed of high acoustic impedance layers 151 and low acoustic impedance layers 152 alternately arranged. An acoustic impedance of a material is equal to a propagation velocity of an acoustic wave in the material multiplied by a density of the material. Theoretically, when a thickness of each high acoustic impedance layer 151 is equal to a quarter of a wavelength of an acoustic wave at a resonant frequency of the bulk acoustic wave resonator propagating in the high acoustic impedance layer 151, and a thickness of each low acoustic impedance layer 152 is equal to a quarter of the wavelength of the acoustic wave at the resonant frequency of the bulk acoustic wave resonator propagating in the low acoustic impedance layer 152, the effect of the high acoustic impedance layers 151 and the low acoustic impedance layers 152 alternately arranged (high/low/high/low . . . , or low/high/low/high . . . ) is equivalent to an acoustic mirror, to reflect the acoustic wave signal leaking from the top. One high acoustic impedance layer 151 and one low acoustic impedance layer 152 as one group form one mirror structure 15, generally 3 groups or 4 groups of the high acoustic impedance layers 151 and the low acoustic impedance layers 152 are needed to achieve a better acoustic reflection effect. Certainly, the greater number of groups may achieve the better acoustic reflection effect, with the increased cost. The number of groups is not limited herein, and the number of the mirror structures 15 may be in a range of 1 to 100. There is no limitation on whether the thickness of each layer is equal to one quarter of the wavelength, and any thickness is acceptable. The high acoustic impedance layer 151 may be made of W, Ir, Pt, Ru, Au, Mo, Ta, Ti, Cu, Ni, Zn, Al, Al₂O₃, Ag, etc. and the common low acoustic impedance layer may be made of SiO₂, Si₃N₄, Mg, rubber, nylon, polyimide, polyethylene, polystyrene, Teflon, etc. The thickness of each high acoustic impedance layer 151 and each low acoustic impedance layer 152 is in a range from 1 nm to 10 μm depending on the different resonance frequencies and the acoustic velocities of different materials.

A material of the first electrode 11 is preferably metal Cu, which has a lattice size is very close to that of the hexagonal phase boron nitride (hBN). Alternatively, the material of the first electrode 11 may be Al, Mo, Co, Ag, Ti, Pt, Ru, W, Au, or an alloy material of any of the above metals. A thickness of the first electrode 11 is in a range of 1 nm to 10 μm.

A material of the second electrode 13 may be selected from Cu, Al, Mo, Co, Ag, Ti, Pt, Ru, W, Au, or an alloy material of any of the above metals. A thickness of the second electrode 13 is in a range of 1 nm to 10 μm.

A material of the encapsulation layer 16 is preferably an organic compound capable of blocking moisture and oxygen, such as polyimide, epoxy, or the like. Alternatively, the material of the encapsulation layer 16 may be an inorganic material such as SiNₓ, Al₂O₃, or the like. The encapsulation layer 16 may be a single layer of material or may be a stack of materials.

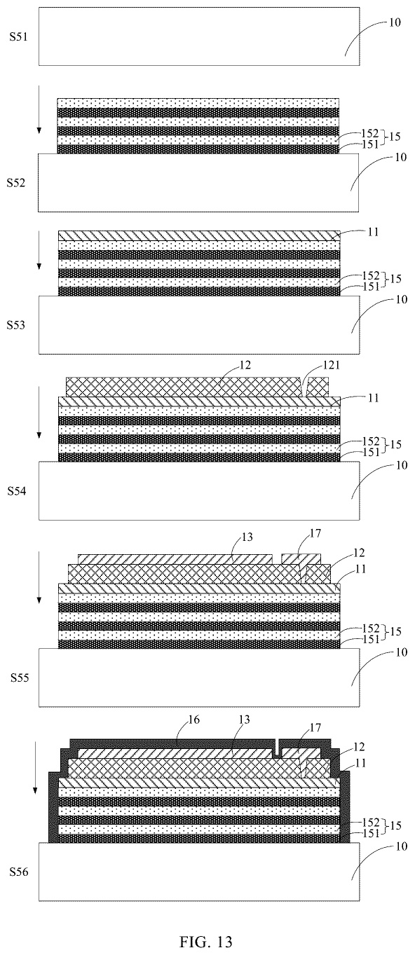

For the bulk acoustic wave resonator shown in FIG. 12, an embodiment of the present disclosure provides a method for manufacturing a bulk acoustic wave resonator. FIG. 13 is a flow chart of manufacturing a bulk acoustic wave resonator shown in FIG. 12. As shown in FIG. 13, the manufacturing method may specifically include the following steps:

S51, providing a first base substrate 10.

In this step, the first base substrate 10 may be cleaned and then dried by air knife.

S52, forming at least one acoustic mirror structure 15 on the first base substrate 10.

In some examples, step S52 may include the following steps (a) and (b). In the step (a), a film material for a high acoustic impedance layer 151 is firstly deposited, preferably by direct current magnetron sputtering (alternatively, radio frequency magnetron sputtering), alternatively by pulsed laser sputtering (PLD), molecular beam epitaxy (MBE), thermal evaporation, electron beam evaporation: processes including coating glue (or spraying glue), pre-baking, exposing, developing, post-baking and etching are performed on the film for the high acoustic impedance layer 151 to form the high acoustic impedance layer 151. The etching process is preferably a wet etching process, or alternatively a dry etching process. In the step (b), a film material for a low acoustic impedance layer 152 is firstly deposited, preferably by direct current magnetron sputtering (alternatively, radio frequency magnetron sputtering), alternatively by pulsed laser sputtering (PLD), molecular beam epitaxy (MBE), thermal evaporation, electron beam evaporation: processes including coating glue (or spraying glue), pre-baking, exposing, developing, post-baking and etching are performed on the film for the low acoustic impedance layer 152 to form the low acoustic impedance layer 152. The etching process is preferably a wet etching process, or alternatively a dry etching process. Thereafter, the steps (a) and (b) are repeated until the at least one acoustic mirror structure 15 satisfying the design requirement on the number of layers is obtained.

S53, forming a first electrode 11 on the first base substrate 10 after the above steps.

In some examples, step S53 may include: depositing a first conductive film on the first base substrate 10, preferably by direct current magnetron sputtering (alternatively, radio frequency magnetron sputtering), alternatively by pulsed laser sputtering (PLD), molecular beam epitaxy (MBE), thermal evaporation, electron beam evaporation, or by attaching a copper foil. Processes including coating glue (or spraying glue), pre-baking, exposing, developing and post-baking are performed on the first conductive film. Finally, an etching process is performed, preferably a wet etching process, or alternatively a dry etching process, to form a pattern including the first electrode 11.

S54, forming a piezoelectric layer 12 on the first base substrate 10 after the above steps.

In some examples, as an example, a material of the piezoelectric layer 12 is hBN, in step S54, an orientation growth of the piezoelectric material may be performed firstly, preferably by radio frequency magnetron sputtering, and a target material is hBN. A hBN oriented film rich in nitrogen vacancies (whose the piezoelectric property is much better than that of BN without nitrogen vacancies) is formed by controlling an air pressure and a temperature of Ar and N2 and a time and temperature of post-annealing in the deposition, and preferably the growth orientation is (100), and may alternatively be (001) and (111). The film deposition method may be selected from pulsed laser sputtering (PLD), molecular beam epitaxy (MBE), metal organic chemical vapor deposition (MOCVD), plasma enhanced chemical vapor deposition (PECVD), and the like. The piezoelectric layer 12 is subjected to a photolithography process including coating glue (or spraying glue), pre-baking, exposing, developing and post-baking. Finally, the piezoelectric material layer is etched to form a pattern of the piezoelectric layer 12 including a first connecting via 121: a preferred etching process may be a wet etching process or a dry etching process.

S55, forming a second electrode 13 and a first connecting electrode 17 on the first base substrate 10 after the above steps.

In some examples, step S55 may include depositing a second conductive film, preferably by direct current magnetron sputtering (alternatively, radio frequency magnetron sputtering), alternatively by pulsed laser sputtering (PLD), molecular beam epitaxy (MBE), thermal evaporation, electron beam evaporation. Processes including coating glue (or spraying glue), pre-baking, exposing, developing and post-baking are performed on the second conductive film. Finally, an etching process is performed, preferably a wet etching process, or alternatively a dry etching process, to form the second electrode 13 and the first connecting electrode 17. The second conductive film formed on a hole wall is thinner, which is not favorable for low-loss transmission of radio frequency signals, so that the second conductive film in the first connecting via 121 may be thickened by an electroplating process, and then patterns of the second electrode 13 and the first connecting electrode 17 are formed.

S56, forming an encapsulation layer 16 on the first base substrate 10 after the above steps.

In some examples, a material of the encapsulation layer 16 may be an organic material polyimide. In this case, step S56 may include performing liquid coating of the organic material, such as spin coating, spraying, ink-jet printing, or transferring or the like, and then performing a heat curing process to form a pattern of the encapsulation layer 16.

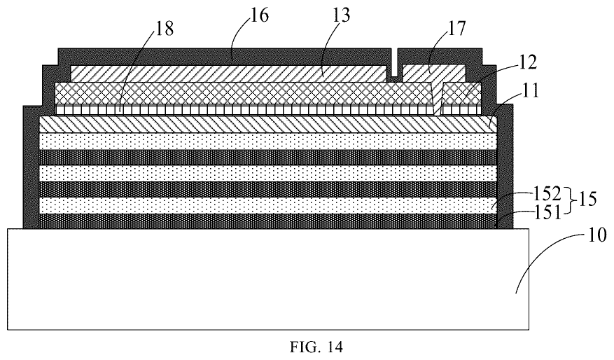

In a sixth example: FIG. 14 is a schematic diagram of a bulk acoustic wave resonator of the sixth example of an embodiment of the present disclosure. As shown in FIG. 14, the bulk acoustic wave resonator includes a first base substrate 10, and at least one acoustic mirror structure 15, a first electrode 11, an inducing layer 18, a piezoelectric layer 12, and a second electrode 13 sequentially disposed on the first base substrate 10. An encapsulation layer 16 may also be provided on a side of the second electrode 13 away from the first base substrate 10. Each mirror structure 15 includes a first sub-structure and a second sub-structure sequentially arranged along a direction away from the first base substrate 10, and an acoustic impedance of a material of the first sub-structure is greater than that of a material of the second sub-structure. For ease of description and understanding, the first sub-structure will be referred to hereinafter as a high acoustic impedance layer 151 and the second sub-structure as a low acoustic impedance layer 152.

Further, in addition to the above structure, the bulk acoustic wave resonator further includes a first connecting electrode 17 disposed in the same layer as the second electrode 13, and connected to the first electrode 11 through a via penetrating through the piezoelectric layer 12. In this case, a radio frequency signal enters into the resonator from an upper left corner of FIG. 14, then is converted into an acoustic wave signal through an inverse piezoelectric effect at an interface between the second electrode 13 and the piezoelectric layer 12, and the acoustic wave signal is longitudinally transmitted in the piezoelectric layer 12, and is converted into a radio frequency signal through the piezoelectric effect at an interface among the first electrode 11, the inducing layer 18 and the piezoelectric layer 12, and is transmitted upward through a conductive through hole at the lower right corner of the first electrode 11, and finally is transmitted outward at the upper right corner of the second electrode 13. The at least one acoustic mirror structure 15 below the resonator and the air layer above the resonator together act as an acoustic reflector, which is configured to confine the acoustic signal within the resonator structure rather than dissipating the acoustic signal out, thereby reducing the losses of the resonator.

In this example, a material of the piezoelectric layer 12 is preferably hBN, and may alternatively be cBN, wBN. Alternatively, the material of the piezoelectric layer 12 may be selected from AlN, ZnO, PZT, GaN, InN, CdS, CdSe, ZnS, CdTe, ZnTe, GaAs, GaSb, InAs, InSb, GaSe, GaP, AlP, quartz crystal, LiTaO3, LiNbO3, La3Ga5SiO14, BaTiO3, PbNb2O6, PBLN, LiGaO3, LiGeO3, TiGeO3, PbTiO3, PbZrO3, PVDF, etc. The piezoelectric layer 12 in the present embodiment may be one of the piezoelectric materials described above, or may be a stack of the above piezoelectric materials. A thickness of the piezoelectric layer 12 is in a range of 10 nm to 100 μm.

A material of the first base substrate 10 is preferably glass, and may alternatively be Si, sapphire, SiC, GaAs, GaN, InP, BN, ZnO, etc. A thickness of the first base substrate 10 is in a range of 0.1 μm to 10 mm.

The at least one acoustic mirror structure 15 is composed of high acoustic impedance layers 151 and low acoustic impedance layers 152 alternately arranged. An acoustic impedance of a material is equal to a propagation velocity of an acoustic wave in the material multiplied by a density of the material. Theoretically, when a thickness of each high acoustic impedance layer 151 is equal to a quarter of a wavelength of an acoustic wave at a resonant frequency of the bulk acoustic wave resonator propagating in the high acoustic impedance layer 151, and a thickness of each low acoustic impedance layer 152 is equal to a quarter of the wavelength of the acoustic wave at the resonant frequency of the bulk acoustic wave resonator propagating in the low acoustic impedance layer 152, the effect of the high acoustic impedance layers 151 and the low acoustic impedance layers 152 alternately arranged (high/low/high/low . . . , or low/high/low/high . . . ) is equivalent to an acoustic mirror, to reflect the acoustic wave signal leaking from the top. One high acoustic impedance layer 151 and one low acoustic impedance layer 152 as one group form one mirror structure 15, generally 3 groups or 4 groups of the high acoustic impedance layers 151 and the low acoustic impedance layers 152 are needed to achieve a better acoustic reflection effect. Certainly, the greater number of groups may achieve the better acoustic reflection effect, with the increased cost. The number of groups is not limited herein, and the number of the mirror structures 15 may be in a range of 1 to 100. There is no limitation on whether the thickness of each layer is equal to one quarter of the wavelength, and any thickness is acceptable. The high acoustic impedance layer 151 may be made of W, Ir, Pt, Ru, Au, Mo, Ta, Ti, Cu, Ni, Zn, Al, Al₂O₃, Ag, etc. and the common low acoustic impedance layer may be made of SiO₂, Si₃N₄, Mg, rubber, nylon, polyimide, polyethylene, polystyrene, Teflon, etc. The thickness of each high acoustic impedance layer 151 and each low acoustic impedance layer 152 is in a range from 1 nm to 10 μm depending on the different resonance frequencies and the acoustic velocities of different materials.

A material of the first electrode 11 is preferably metal Cu, which has a lattice size is very close to that of the hexagonal phase boron nitride (hBN). Alternatively, the material of the first electrode 11 may be Al, Mo, Co, Ag, Ti, Pt, Ru, W, Au, or an alloy material of any of the above metals. A thickness of the first electrode 11 is in a range of 1 nm to 10 μm.

The inducing layer 18 is located between the first electrode 11 and the piezoelectric layer 12, and configured to assist the growth of the piezoelectric layer 12, so that an orientation of the piezoelectric layer 12 is C-axis orientation (an acoustic velocity of the piezoelectric layer 12 along a C axis is the highest), and a quality of the material of the piezoelectric layer 12 is improved (for example, a full width at half maximum of a rocking curve of X-ray diffraction is less than) 1.5°. In this embodiment, the inducing layer 18 is preferably made of graphene, and may be single-layer graphene, or may be double-layer graphene or multi-layer graphene. That is, a thickness of the inducing layer 18 is in a range of 0.1 nm to 100 nm.

A material of the second electrode 13 may be selected from Cu, Al, Mo, Co, Ag, Ti, Pt, Ru, W, Au, or an alloy material of any of the above metals. A thickness of the second electrode 13 is in a range of 1 nm to 10 μm.

A material of the encapsulation layer 16 is preferably an organic compound capable of blocking moisture and oxygen, such as polyimide, epoxy, or the like. Alternatively, the material of the encapsulation layer 16 may be an inorganic material such as SiNₓ, Al₂O₃, or the like. The encapsulation layer 16 may be a single layer of material or may be a stack of materials.

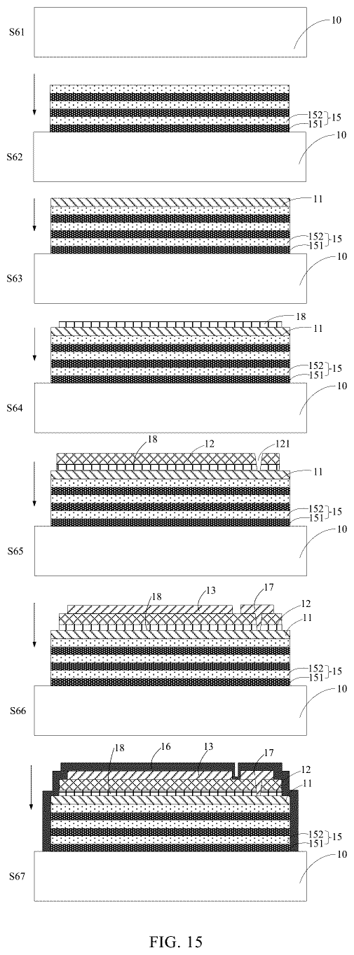

For the bulk acoustic wave resonator shown in FIG. 14, an embodiment of the present disclosure provides a method for manufacturing a bulk acoustic wave resonator. FIG. 15 is a flow chart of manufacturing a bulk acoustic wave resonator shown in FIG. 14. As shown in FIG. 15, the manufacturing method may specifically include the following steps:

S61, providing a first base substrate 10.

In this step, the first base substrate 10 may be cleaned and then dried by air knife.

S62, forming at least one acoustic mirror structure 15 on the first base substrate 10.

In some examples, step S62 may include the following steps (a) and (b). In the step (a), a film material for a high acoustic impedance layer 151 is firstly deposited, preferably by direct current magnetron sputtering (alternatively, radio frequency magnetron sputtering), alternatively by pulsed laser sputtering (PLD), molecular beam epitaxy (MBE), thermal evaporation, electron beam evaporation: processes including coating glue (or spraying glue), pre-baking, exposing, developing, post-baking and etching are performed on the film for the high acoustic impedance layer 151 to form the high acoustic impedance layer 151. The etching process is preferably a wet etching process, or alternatively a dry etching process. In the step (b), a film material for a low acoustic impedance layer 152 is firstly deposited, preferably by direct current magnetron sputtering (alternatively, radio frequency magnetron sputtering), alternatively by pulsed laser sputtering (PLD), molecular beam epitaxy (MBE), thermal evaporation, electron beam evaporation: processes including coating glue (or spraying glue), pre-baking, exposing, developing, post-baking and etching are performed on the film for the low acoustic impedance layer 152 to form the low acoustic impedance layer 152. The etching process is preferably a wet etching process, or alternatively a dry etching process. Thereafter, the steps (a) and (b) are repeated until the at least one acoustic mirror structure 15 satisfying the design requirement on the number of layers is obtained.

S63, forming a first electrode 11 on the first base substrate 10 after the above steps.

In some examples, step S63 may include: depositing a first conductive film on the first base substrate 10, preferably by direct current magnetron sputtering (alternatively, radio frequency magnetron sputtering), alternatively by pulsed laser sputtering (PLD), molecular beam epitaxy (MBE), thermal evaporation, electron beam evaporation, or by attaching a copper foil. Processes including coating glue (or spraying glue), pre-baking, exposing, developing and post-baking are performed on the first conductive film. Finally, an etching process is performed, preferably a wet etching process, or alternatively a dry etching process, to form a pattern including the first electrode 11.

S64, forming an inducing layer 18 on the first base substrate 10 after the above steps.

In some examples, a material of the inducing layer 18 is preferably a graphene film, and may be single-layer, or may be double-layer or multi-layer. If the material of the first electrode 11 formed in step S63 is a metal, such as Fe, Ru, Co, Rh, Ir, Ni, Pd, Pt. Cu, Au, or an alloy, such as Co—Ni, Au—Ni, by taking the inducing layer 18 as the graphene material as an example, the graphene material may be directly grown by magnetron sputtering chemical vapor deposition or microwave plasma chemical vapor deposition, which specifically includes: introducing a mixed gas of methane, nitrogen and argon, and heating the substrate to 600° C. to 800° C., and generating the graphene film through a reaction. If the first electrode 11 formed in step S63 is not the above metal or alloy, the inducing layer may be formed in two steps: (a) the first step of forming the graphene film, including putting a metal foil, such as a foil of a metal, such as Fe, Ru, Co, Rh, Ir, Ni, Pd, Pt, Cu, Au or an alloy, such as Co—Ni, Au—Ni, into a reaction chamber: growing the graphene material by magnetron sputtering chemical vapor deposition or microwave plasma chemical vapor deposition, which specifically includes: introducing a mixed gas of methane, nitrogen and argon, and heating the substrate to 600° C. to 800° C., and generating the graphene film through a reaction: (b) the second step of transferring the formed graphene film from the metal foil to the first electrode 11, including firstly, spraying or spin-coating polymethyl methacrylate (PMMA) on the metal foil/graphene in an inert gas atmosphere, and heating the metal foil/graphene at 120° C. for 3 minutes to 5 minutes for drying and curing: putting the metal foil/graphene/PMMA into a corresponding solution to dissolve the metal away, for example, putting the copper foil into a 20% FeCl3 solution, wherein the rest graphene/PMMA is floating on the surface of the solution; taking out the graphene/PMMA from the solution, putting the graphene/PMMA into deionized water for cleaning, transferring the graphene/PMMA onto the first electrode 11; irradiating the graphene/PMMA for 10 minutes to 15 minutes by using an infrared lamp for drying; and finally dissolving the PMMA away by using an organic solvent such as acetone. The inducing layer 18 has been formed.

S65, forming a piezoelectric layer 12 on the first base substrate 10 after the above steps.

In some examples, as an example, a material of the piezoelectric layer 12 is hBN, in step S65, an orientation growth of the piezoelectric material may be performed firstly, preferably by radio frequency magnetron sputtering, and a target material is hBN. A hBN oriented film rich in nitrogen vacancies (whose the piezoelectric property is much better than that of BN without nitrogen vacancies) is formed by controlling an air pressure and a temperature of Ar and N2 and a time and temperature of post-annealing in the deposition, and preferably the growth orientation is (100), and may alternatively be (001) and (111). The film deposition method may be selected from pulsed laser sputtering (PLD), molecular beam epitaxy (MBE), metal organic chemical vapor deposition (MOCVD), plasma enhanced chemical vapor deposition (PECVD), and the like. The piezoelectric layer 12 is subjected to a photolithography process including coating glue (or spraying glue), pre-baking, exposing, developing and post-baking. Finally, the piezoelectric material layer is etched to form a pattern of the piezoelectric layer 12 with a first connecting via 121: a preferred etching process may be a wet etching process or a dry etching process.

S66, forming a second electrode 13 and a first connecting electrode 17 on the first base substrate 10 after the above steps.

In some examples, step S66 may include depositing a second conductive film, preferably by direct current magnetron sputtering (alternatively, radio frequency magnetron sputtering), alternatively by pulsed laser sputtering (PLD), molecular beam epitaxy (MBE), thermal evaporation, electron beam evaporation. Processes including coating glue (or spraying glue), pre-baking, exposing, developing and post-baking are performed on the second conductive film. Finally, an etching process is performed, preferably a wet etching process, or alternatively a dry etching process, to form the second electrode 13 and the first connecting electrode 17. The second conductive film formed on a hole wall is thinner, which is not favorable for low-loss transmission of radio frequency signals, so that the second conductive film in the first connecting via 121 may be thickened by an electroplating process, and then patterns of the second electrode 13 and the first connecting electrode 17 are formed.

S67, forming an encapsulation layer 16 on the first base substrate 10 after the above steps.

In some examples, a material of the encapsulation layer 16 may be an organic material polyimide. In this case, step S67 may include performing liquid coating of the organic material, such as spin coating, spraying, ink-jet printing, or transferring or the like, and then performing a heat curing process to form a pattern of the encapsulation layer 16.

The embodiment of the present disclosure further provides an electronic device, which may include the bulk acoustic wave resonator of any one of the above embodiments.

It should be understood that the above embodiments are merely exemplary embodiments adopted to explain the principles of the present disclosure, and the present disclosure is not limited thereto. It will be apparent to one of ordinary skill in the art that various changes and modifications may be made therein without departing from the spirit and scope of the present disclosure, and such changes and modifications also fall within the scope of the present disclosure.

1. A bulk acoustic wave resonator, comprising: a first base substrate, a first electrode, a piezoelectric layer, and a second electrode; wherein the first electrode is on the first base substrate, the second electrode is on a side of the first electrode away from the first base substrate, the piezoelectric layer is between the first electrode and the second electrode; and orthographic projections of any two of the first electrode, the piezoelectric layer and the second electrode on the first base substrate at least partially overlap with each other; wherein an acoustic velocity of a material of the piezoelectric layer is no less than 18000 m/s.

2. The bulk acoustic wave resonator according to claim 1, wherein the material of the piezoelectric layer comprises any one of hBN, cBN, wBN.

3. The bulk acoustic wave resonator according to claim 1, further comprising an inducing layer between the first electrode and the piezoelectric layer, wherein an orthographic projection of the inducing layer on the first base substrate covers an orthographic projection of the piezoelectric layer on the first base substrate.

4. The bulk acoustic wave resonator according to claim 3, wherein a material of the inducing layer comprises graphene.

5. The bulk acoustic wave resonator according to claim 1, further comprising a first connecting electrode in a same layer as the second electrode, wherein the first connecting electrode is electrically connected to the first electrode through a first connecting via penetrating through the piezoelectric layer.

6. The bulk acoustic wave resonator according to claim 1, wherein a material of the first electrode comprises any one or more of Cu, Al, Mo, Co, Ag, Ti, Pt, Ru, W and Au.

7. The bulk acoustic wave resonator according to claim 1, wherein the first base substrate comprises a first cavity penetrating through the first base substrate in a thickness direction of the first base substrate; the first base substrate comprises a first surface and a second surface opposite to each other in the thickness direction of the first base substrate; the first cavity comprises a first opening and a second opening opposite to each other; and the first opening is in the first surface, and the second opening is in the second surface; and the first electrode covers the first opening.

8. The bulk acoustic wave resonator according to claim 1, wherein the first base substrate comprises a first groove; the first base substrate comprises a first surface and a second surface opposite to each other in a thickness direction of the first base substrate; the first groove comprises a third opening; and the third opening is in the first surface, the first electrode is on the first surface; and an orthographic projection of the third opening on the second surface is within an orthographic projection of the first electrode on the second surface.

9. The bulk acoustic wave resonator according to claim 8, further comprising an isolation layer between the first surface of the first base substrate and the first electrode.

10. The bulk acoustic wave resonator according to claim 9, further comprising at least one first through hole penetrating through the first electrode and the isolation layer, wherein the first via is connected to and communicates with the first groove.

11. The bulk acoustic wave resonator according to claim 1, further comprising at least one mirror structure between the first electrode and the first base substrate; wherein each of the at least one mirror structure comprises a first sub-structure layer and a second sub-structure layer sequentially arranged in a direction away from the first base substrate, and an acoustic impedance of a material of the first sub-structure layer is greater than that of a material of the second sub-structure layer.

12. The bulk acoustic wave resonator according to claim 1, further comprising an encapsulation layer on a side of the second electrode away from the first base substrate, wherein the encapsulation layer covers the first electrode, the piezoelectric layer and the second electrode.

13. A method for manufacturing a bulk acoustic wave resonator, comprising: sequentially forming a first electrode, a piezoelectric layer and a second electrode on a first base substrate, wherein orthographic projections of any two of the first electrode, the piezoelectric layer and the second electrode on the first base substrate at least partially overlap with each other; wherein an acoustic velocity of a material of the piezoelectric layer is no less than 18000 m/s.

14. (canceled)

15. The method for manufacturing a bulk acoustic wave resonator according to claim 13, wherein the forming the piezoelectric layer comprises: forming the piezoelectric layer by a radio frequency magnetron sputtering process; and
wherein before forming the first electrode and the piezoelectric layer, the method further comprises: forming an inducing layer.

16. (canceled)

17. The method for manufacturing a bulk acoustic wave resonator according to claim 15, further comprising forming a first connecting electrode while forming the second electrode;
wherein the method further comprises: forming a first connecting via penetrating through the piezoelectric layer in a thickness direction of the piezoelectric layer, and the first connecting electrode is connected to the first electrode through the first connecting via.

18. The method for manufacturing a bulk acoustic wave resonator according to claim 13, further comprising: forming a first cavity penetrating through the first base substrate in a thickness direction of the first base substrate by performing a treatment on the first base substrate; wherein the first base substrate comprises a first surface and a second surface opposite to each other in the thickness direction of the first base substrate; the first cavity comprises a first opening and a second opening opposite to each other; and the first opening is in the first surface, and the second opening is in the second surface; and the first electrode covers the first opening.

19. The method for manufacturing a bulk acoustic wave resonator according to claim 13, further comprising: forming a first groove by performing a treatment on the first base substrate; wherein the first base substrate comprises a first surface and a second surface opposite to each other in a thickness direction of the first base substrate; the first groove comprises a third opening; and the third opening is in the first surface, the first electrode is on the first surface; and an orthographic projection of the third opening on the second surface is within an orthographic projection of the first electrode on the second surface.

20. The method of manufacturing a bulk acoustic wave resonator according to claim 19, further comprising:
forming a filling structure in the first groove;
forming an isolation layer on a side of the first groove away from the first base substrate; wherein the first electrode is formed on a side of the isolation layer away from the first base substrate; and
forming a first through hole penetrating through the first electrode and the isolation layer, and removing the filling structure by an etching process via the first through hole.

21. The method for manufacturing a bulk acoustic wave resonator according to claim 13, wherein before the forming the first electrode, the method further comprises:
forming at least one mirror structure on the first base substrate such that each of the at least one mirror structure comprises a first sub-structure layer and a second sub-structure layer sequentially arranged in a direction away from the first base substrate, and an acoustic impedance of a material of the first sub-structure layer is greater than that of a material of the second sub-structure layer.

22. (canceled)

23. An electronic device, comprising the bulk acoustic wave resonator according to claim 1.
